(19) United States
(12) Patent Application Publication
(10) Pub. No.: US 2019/0035728 A1
(43) Pub. Date: Jan. 31, 2019

(54) INTEGRATED ELECTRONIC DEVICE WITH A REDISTRIBUTION REGION AND A HIGH RESILIENCE TO MECHANICAL STRESSES

(71) Applicant: STMicroelectronics S.r.l., Agrate Brianza (IT)

(72) Inventors: Ivan Venegoni, Bareggio (IT); Francesca Milanesi, Milano (IT); Francesco Maria Pipia, Milano (IT); Samuele Sciarrillo, Usmate Velate (IT); Paolo Colpani, Agrate Brianza (IT)

(21) Appl. No.: 16/044,190

(22) Filed: Jul. 24, 2018

(30) Foreign Application Priority Data
Jul. 28, 2017 (IT) 102017000087309

(51) Int. Cl. H01L 23/522; H01L 21/768; H01L 23/532

(52) U.S. Cl. CPC H01L 23/5226; H01L 21/76802; H01L 21/76843; H01L 23/53252; H01L 23/53238

(57) ABSTRACT

An integrated device includes a semiconductor body and a dielectric layer bounded by a surface. A conductive region of a first metal material forms a via region extending into a hole passing through the dielectric layer, and an overlaid redistribution region which extends over the surface. At least one barrier region of a second metal material extends into the hole and surrounds the via region, and the barrier region furthermore extending over the surface. A first coating layer of a third metal material covers the top and the sides of an upper portion of the redistribution region at a distance from the surface. A second coating layer of a fourth metal material extends at a distance from the surface and covers the first coating layer, and covers laterally a lower portion of the redistribution region which is disposed on top of portions of the barrier region extending over the surface.

### BACKGROUND

### Technical Field

The present disclosure relates to an integrated electronic device, which includes a redistribution region and has a high resilience to mechanical stresses.

### Description of the Related Art

As is known, in the field of technologies for fabricating semiconductor circuits, reference is generally made to the redistribution layer (RDL) in order to indicate an additional metal layer of an integrated circuit (“chip”) formed within a die, which allows the input/output pads (I/O) formed within the same die to be rendered electrically accessible. In other words, the redistribution layer is a metal layer connected to the I/O pads, to which the wires which allow the ‘wire bonding’ may, for example, be connected in different positions with respect to the positions in which the pads are disposed. The redistribution layer thus allows, for example, the processes of electrical connection between chips to be simplified.

One example of use of the redistribution layer is shown schematically in FIG. 1, where an integrated electronic device 10 is shown.

In detail, the integrated electronic device 10 is formed within a die 4, which includes a body of semiconductor material 6, which is bounded by an upper surface Sᵤₚ and, although not shown, may include regions with different types and levels of doping. Furthermore, the integrated electronic device 10 comprises a frontal structure 8, which extends over the upper surface Sᵤₚ.

The frontal structure 8 comprises a plurality of dielectric layers, disposed in a stack; for example, in FIG. 1 a first, a second, a third, a fourth, a fifth, a sixth, a seventh and an eighth dielectric layer are shown, which are at decreasing distances relative to the upper surface Sᵤₚ, are respectively indicated with 11, 12, 14, 16, 17, 18, 19 and 20 and form a passivation structure 21 through which metal interconnects are defined.

The frontal structure 8 furthermore comprises a number of first metallizations M1, to which reference is henceforth made as proximal metallizations M1, as well as a number of second and third metallizations M2, M3, to which reference is henceforth respectively made as intermediate metallizations M2 and as distal metallizations M3. The intermediate metallizations M2 extend, at a distance, between the proximal metallizations M1 and the distal metallizations M3.

The distal metallizations M3 extend through the third dielectric layer 14, hence they open out onto the fourth dielectric layer 16.

The intermediate metallizations M2 extend through the fifth dielectric layer 17, hence they open out onto the fourth and onto the sixth dielectric layer 16, 18.

The proximal metallizations M1 extend through the seventh dielectric layer 19, hence they open out onto the sixth 18 and onto the eighth dielectric layer 20.

The frontal structure 8 also comprises a number of contact regions CR formed by metal material, which extend through the tenth dielectric layer 20 in such a manner as to open out onto the semiconductor body 6, with which they are in direct contact. Furthermore, the contact regions CR are in contact with corresponding first metallizations M1, disposed on top of these.

The frontal structure 8 furthermore comprises a plurality of first vias V1, to which reference is henceforth made as proximal vias V1, as well as a number of second and third vias V2, V3, to which reference is henceforth respectively made as intermediate vias V2 and as distal vias V3. Each proximal via V1 electrically connects a proximal metallization M1 and a corresponding intermediate metallization M2; each intermediate via V2 electrically connects an intermediate metallization M2 and a corresponding distal metallization M3.

Each distal via V3 extends into a corresponding hole T, which passes through the first and the second dielectric layer 11, 12. In this regard, the first dielectric layer 11 is typically formed from silicon nitride (SiN); the first dielectric layer 11 is bounded on top by a surface S_{front}, to which reference is henceforth made as frontal surface S_{front}. The second dielectric layer 12 is formed, for example, from silicon oxide. The sum of the thicknesses of the dielectric layers 11 and 12 may for example be greater than 1 μm.

The bottom of the hole T is thus bounded by a corresponding distal metallization M3, whereas the sidewall of the hole T is bounded by the first and by the second dielectric layer 11, 12. Furthermore, the bottom and the sidewall of the hole T are covered, in direct contact, by a first patterned barrier layer 22, which can for example have a thickness greater than 100 nm and may be composed of titanium (Ti) or tantalum (Ta), or else made of an alloy containing titanium or tantalum (for example, TiN, TiW, TaNTa). The first patterned barrier layer 22 furthermore extends in part over the top of the frontal surface S_{front}, in direct contact with the first dielectric layer 11.

The first patterned barrier layer 22 is, in turn, covered by a further layer 24, to which reference is henceforth also made as patterned seed layer 24.

The patterned seed layer 24 is typically formed from copper and may for example have a thickness greater than 10 nm. The patterned seed layer 24 thus extends into the inside of the hole T, in such a manner as to cover the portions of the first patterned barrier layer 22 which cover the bottom and the sidewall of the hole T. Furthermore, the patterned seed layer 24 extends over the top of the portions of the first patterned barrier layer 22 which extend over the top of the first dielectric layer 11.

The frontal structure 8 furthermore comprises a conductive region 25, to which reference is henceforth made as redistribution layer 25.

The redistribution layer 25 is formed from the same conductive material as that forming the distal vias V3. The redistribution layer 25 is thus typically formed from copper, is patterned and overlies the distal vias V3, with which it forms a single monolithic region. Furthermore, the redistribution layer 25 may for example have a thickness greater than 1 μm.

The redistribution layer 25 also extends over the top of the portions of the patterned seed layer 24 disposed on top of the frontal surface S_{front}. In more detail, the patterned seed layer 24 also forms the aforementioned monolithic region, together with the redistribution layer 25 and the distal vias V3.

The frontal structure 8 furthermore comprises a first coating layer 30, which covers the top and the sides of the redistribution layer 25, as far as making contact with portions of the first dielectric layer 11. The first coating layer 30 is typically formed from nickel or from one of its alloys (for example NiP, NiPW, NiPMo).

In greater detail, the first coating layer 30 covers laterally the portions of the patterned seed layer 24 which extend over the top of the frontal surface S_{front}, as well as the portions of the first patterned barrier layer 22 which extend over the top of the frontal surface S_{front}. As a consequence, lower portions of the first coating layer 30 make contact, aside from the first dielectric layer 11, with portions of the first patterned barrier layer 22 which extend over the top of the frontal surface S_{front}, as well as overlying portions of the patterned seed layer 24.

The frontal structure 8 furthermore comprises a second coating layer 32, which is typically formed from a noble metal, such as for example gold, palladium or a combination of both (Pd/Au); the combined thickness of the first and second coating layers 30, 32 may for example be greater than 1 μm. Typically, in the step of fabrication, the second coating layer 32 is formed without applying electric fields (“electroless” deposition technique).

In detail, the second coating layer 32 is deposited on top of the first coating layer 30, with which it is in direct contact. The second coating layer 32 thus surrounds the redistribution layer 25 on the top and sides, at a distance, until it makes contact with the first dielectric layer 11.

In practice, the first and the second coating layers 30, 32 form a capping structure, which covers the redistribution layer 25 and makes contact with the first dielectric layer 11.

For practical reasons, the first coating layer 30 is formed by a material (nickel) having a greater hardness compared with the material (copper) which forms the redistribution layer 25, the latter material having a higher conductivity. The first coating layer 30 provides rigidity to the frontal structure 8 during the bonding steps, so as to prevent the deformation of the redistribution layer 25. Furthermore, the first coating layer 30 serves as a barrier against the migration/electromigration of the material forming the redistribution layer 25.

As far as, on the other hand, the second coating layer 32 is concerned, this is formed by a noble metal and thus prevents the underlying metals from being subjected to oxidation or corrosion.

Compared with the first patterned barrier layer 22, this is metal and furthermore serves as a barrier against the migration to the first dielectric layer 11 of the material that forms the redistribution layer 25. Furthermore, the first patterned barrier layer 22 improves the adhesion between the patterned seed layer 24 and the underlying layers.

In light of the above, because of the different mechanical characteristics of the materials that form the redistribution layer 25, the first dielectric layer 11 and the first and second coating layers 30, 32, it is possible for the integrated electronic device 10 to be subjected to excessive mechanical stresses, which may compromise its operation. In particular, the stresses arise for example in the case in which the fabrication process includes the execution of steps with a high thermal budget.

### BRIEF SUMMARY

In one embodiment of the present disclosure, an integrated electronic device includes a semiconductor body and a passivation structure including a frontal dielectric layer bounded by a frontal surface. A conductive region of a first metal material forms a via region which extends into a hole passing through the frontal dielectric layer and an overlaid redistribution region which extends over the frontal surface. A barrier structure includes at least a first barrier region of a second metal material which extends into the hole and surrounds the via region. The first barrier region furthermore extends over the frontal surface. A first coating layer of a third metal material covers the top and the sides of an upper portion of the redistribution region at a distance from the frontal surface. A second coating layer of a fourth metal material extends at a distance from the frontal surface and covers the first coating layer and covers laterally a lower portion of the redistribution region which is disposed on top of portions of the barrier structure which extend over the frontal surface.

### BRIEF DESCRIPTION OF THE SEVERAL VIEWS OF THE DRAWINGS

For a better understanding of the present disclosure, embodiments thereof are now described, purely by way of non-limiting example and with reference to the appended drawings, in which:

FIG. 1 shows schematically a transverse cross section (not to scale) of a portion of an integrated electronic device;

FIGS. 2, 13 and 24 show schematically transverse cross sections (not to scale) of portions of embodiments of the present integrated electronic device;

FIGS. 3-12 show schematically transverse cross sections of portions of the embodiment shown in FIG. 2, during successive steps of a fabrication process according to an embodiment of the present disclosure; and

FIGS. 14-23 show schematically transverse cross sections of portions of the embodiment shown in FIG. 13, during successive steps of a fabrication process according to an embodiment of the present disclosure;

FIGS. 25-29 show schematically transverse cross sections of portions of the embodiment shown in FIG. 24, during successive steps of a fabrication process according to an embodiment of the present disclosure; and

FIG. 30 shows schematically a transverse cross section of an integrated electronic circuit (or ‘chip’) which includes the present integrated electronic device.

### DETAILED DESCRIPTION

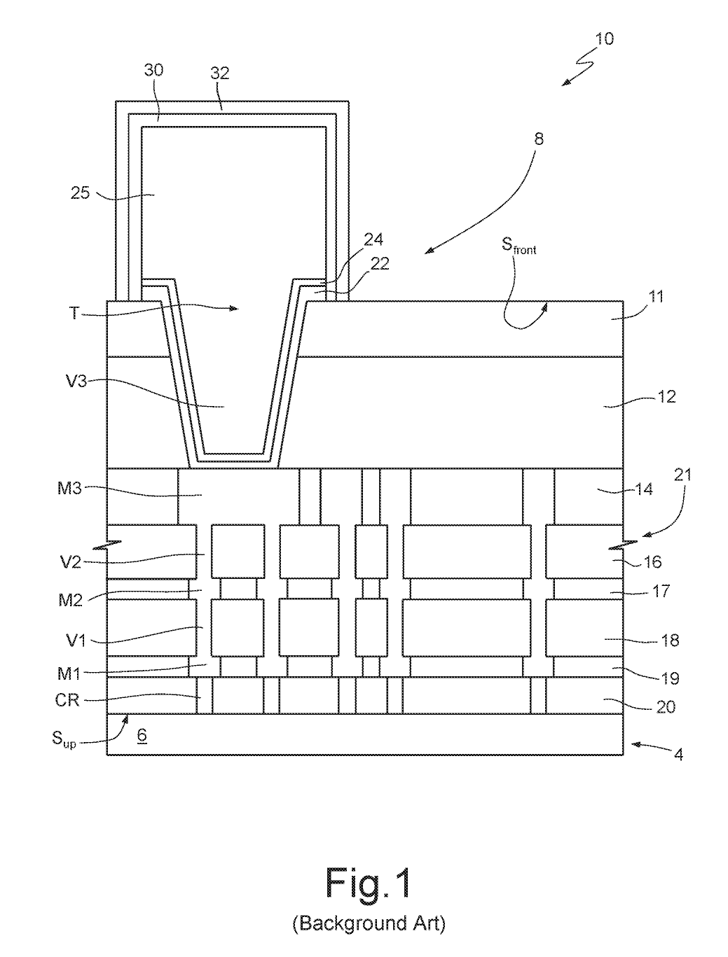

In the following, the present integrated electronic device is described, without any loss of generality, with reference to the differences compared with that shown in FIG. 1. Elements already present in the integrated electronic device 10 shown in FIG. 1 will be indicated with the same reference symbols, unless specified otherwise.

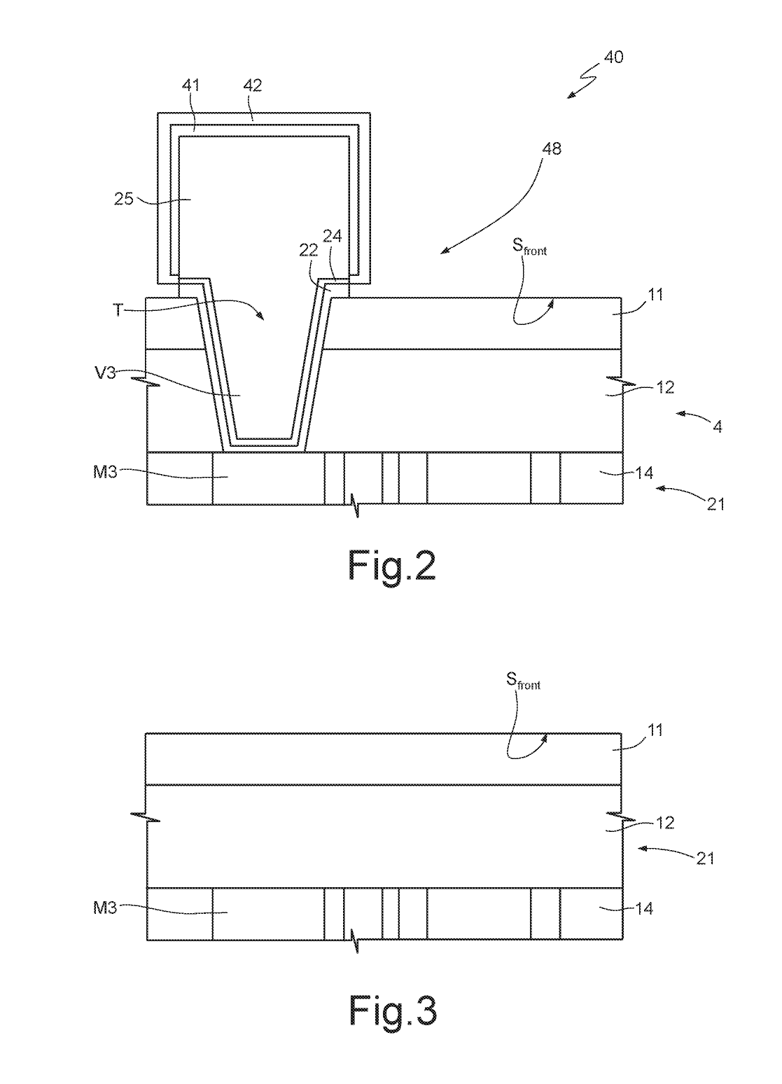

A first embodiment of the present integrated electronic device is shown in FIG. 2, where it is indicated with 40. In particular, FIG. 2 shows only an upper portion of the integrated electronic device 40, given that the elements disposed underneath the third dielectric layer 14 are not shown.

This having been said, the first coating layer, here indicated with 41, covers the top and the sides of an upper portion of the redistribution layer 25 and is disposed at a distance from the first dielectric layer 11, i.e., it is physically separated from the latter. Furthermore, the first coating layer 41 is physically separated from the first patterned barrier layer 22 and from the patterned seed layer 24, given that it extends at the bottom to a height which is higher than the maximum height reached by the patterned seed layer 24. Consequently, the first coating layer 41 leaves a lower portion of the redistribution layer 25 laterally exposed, together with portions of the patterned seed layer 24 and of the first patterned barrier layer 22, these portions being laterally offset with respect to the hole T and being disposed on top of the frontal surface S_{front}.

The second coating layer, here indicated with 42, entirely covers the first coating layer 41 and is physically separated from the first dielectric layer 11.

In particular, the second coating layer 42 extends at the bottom as far as laterally covering the exposed portions of the redistribution layer 25 and of the patterned seed layer 24, but leaves exposed portions of the first patterned barrier layer 22. In other words, the second coating layer 42 extends at the bottom to a minimum height which is not higher than the maximum height reached by the first patterned barrier layer 22; therefore, the second coating layer 42 makes contact with the first patterned barrier layer 22.

In practice, in the frontal structure of the integrated electronic device 40, indicated with 48, the first and the second coating layers 41, 42 do not make contact with the first dielectric layer 11, thus reducing the mechanical stress exerted on the passivation structure 21. In an equivalent manner, the integrated electronic device 40 is lacking points at which the first patterned barrier layer 22, the first coating layer 41 and the first dielectric layer 11 are in contact; these points represent points at which the structure formed by the redistribution layer 25 and by the first and second coating layers 41, 42 exerts the maximum mechanical stress during the processes at high temperature.

The embodiment shown in FIG. 2 may be obtained by implementing the following fabrication process.

Initially, as shown in FIG. 3, the die 4 (not shown in FIG. 3) is arranged and the vias, the metallizations and the passivation structure 21 are formed within it.

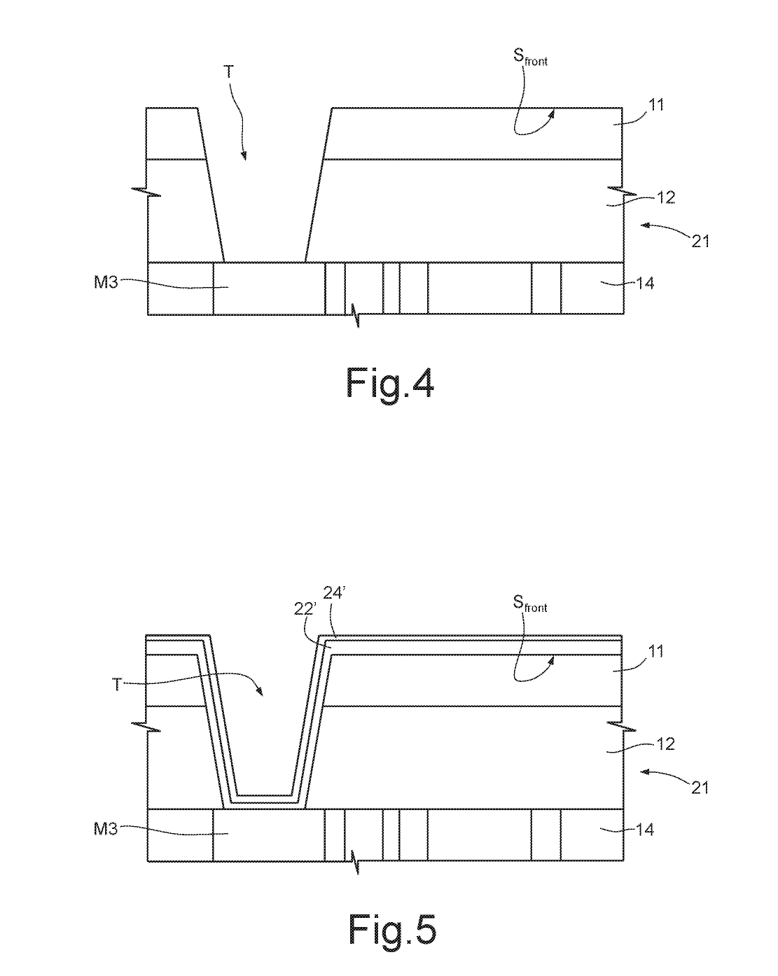

Subsequently, as shown in FIG. 4, portions of the first and of the second dielectric layers 11, 12 are selectively removed starting from the frontal surface S_{front}, in such a manner as to form the hole T. For example, a dry etch is carried out, limited by the distal metallization M3, and then a wet etch is carried out, so as to expose a portion of a distal metallization M3.

Subsequently, as shown in FIG. 5, a first barrier layer 22′, destined to form the first patterned barrier layer 22, and a seed layer 24′, destined to form the patterned seed layer 24, are formed by means of deposition. The first barrier layer 22′ extends over the frontal surface S_{front} and covers the sidewall and the bottom of the hole T, while the seed layer 24′ extends over the first barrier layer 22′.

The first barrier layer 22′ and the seed layer 24′ are respectively formed from the same materials as the first patterned barrier layer 22 and as the patterned seed layer 24. Furthermore, the first barrier layer 22′ and the seed layer 24′ may both have a thickness greater than 100 nm.

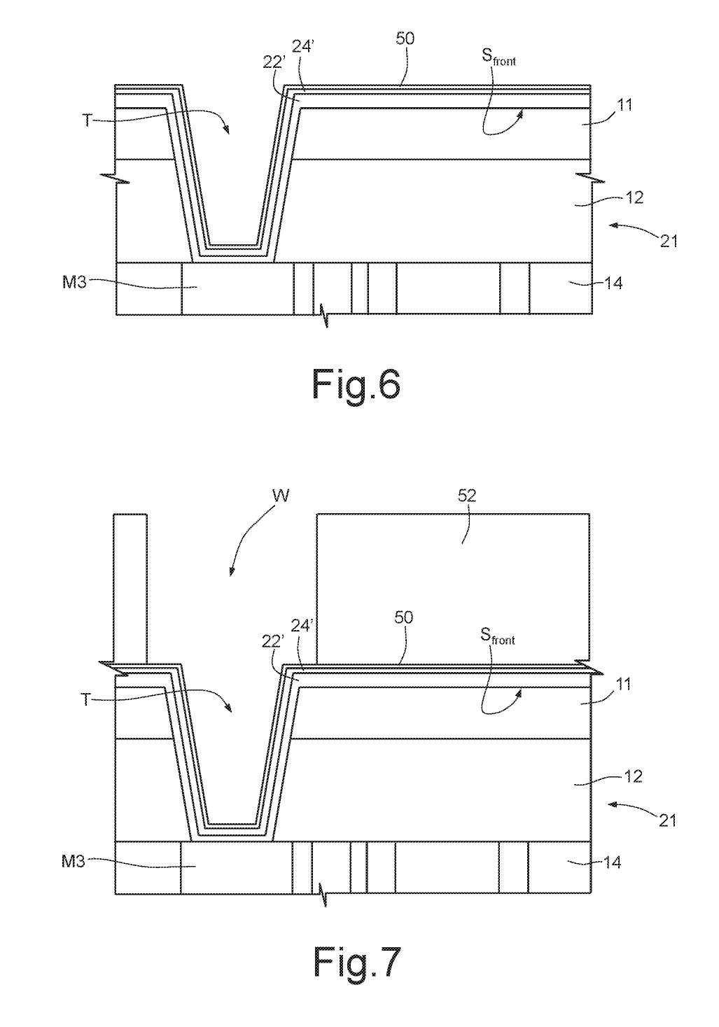

Subsequently, as shown in FIG. 6, a dielectric layer 50, to which reference is henceforth made as sacrificial layer 50, is formed on top of the seed layer 24′, for example by means of chemical vapor deposition (or CVD).

The sacrificial layer 50 has a thickness for example of less than 100 nm and may be quickly removed both by means of a dry etch and by means of a wet etch. The sacrificial layer 50 is formed, for example by means of chemical vapor deposition, from silicon nitride, which is deposited for example using a low temperature process, or else from silicon oxide.

Subsequently, as shown in FIG. 7, a resist mask 52 defining a window W over the hole T is formed on top of the sacrificial layer 50. The formation of the resist mask 52 includes for example the formation on the sacrificial layer 50 of a layer of resist and subsequently the patterning of this layer of resist by means of photolithography.

In greater detail, the window W is such that it exposes a portion of the sacrificial layer 50 covering the portion of seed layer 24′ disposed inside of the hole T and portions of the seed layer 24′ that laterally protrude from the hole T over the frontal surface S_{front}.

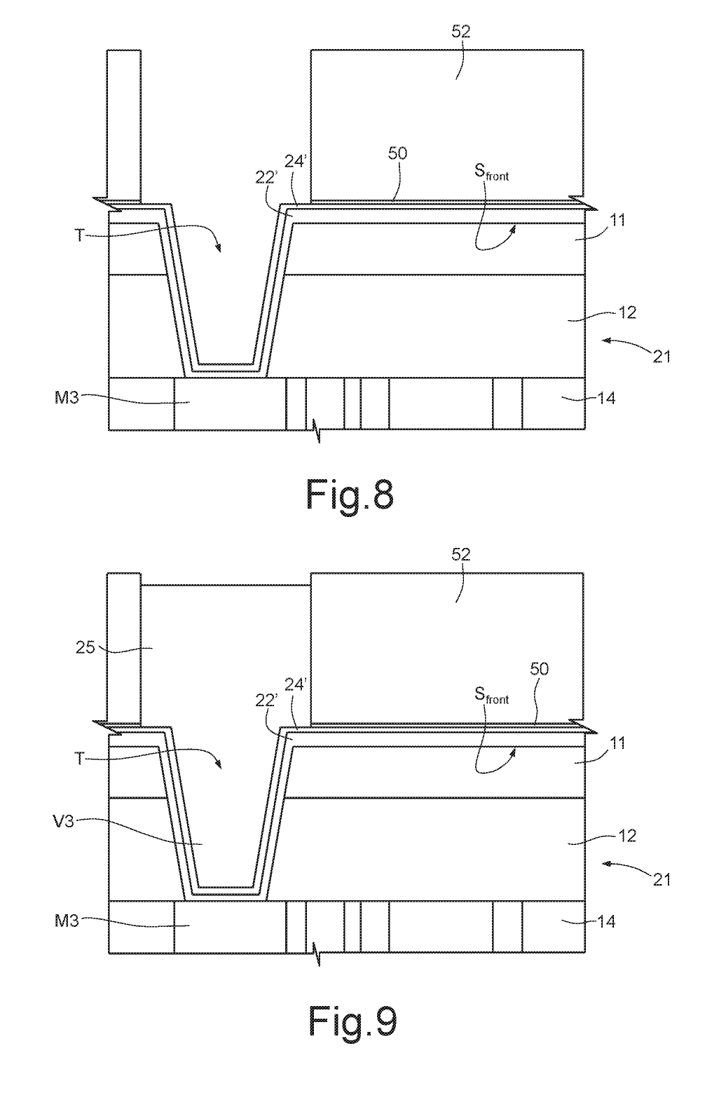

Subsequently, as shown in FIG. 8, the resist mask 52 is employed to selectively remove the exposed portion of the sacrificial layer 50, for example by means of a wet etch using hydrogen fluoride (HF) or a plasma etch of the type using reactive ions (‘reactive ion etching’ or RIE), with a fluorocarbon gas. In this way, portions of the seed layer 24′ are exposed.

Subsequently, as shown in FIG. 9, the redistribution layer 25 and the distal vias V3 are formed, which are monolithic with one another and are formed from the same material as the seed layer 24′ (for example, copper). The redistribution layer 25 and the distal vias V3 are formed for example by means of electrochemical deposition (or ECD), with growth starting from the exposed portions of the seed layer 24′. Furthermore, the presence of the resist mask 52 allows the redistribution layer 25 to be patterned.

In more detail, the redistribution layer 25 and the distal vias V3 form a single monolithic region together with the seed layer 24′, although, for the sake of clarity, the latter layer is shown as separate.

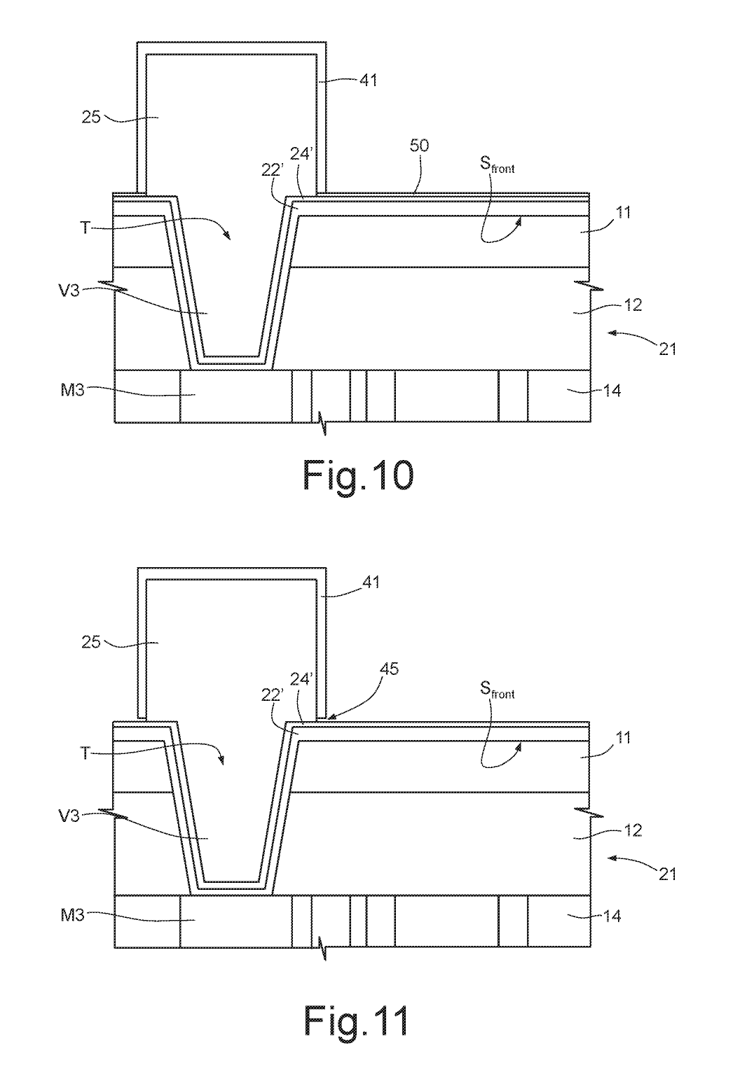

Subsequently, as shown in FIG. 10, the resist mask 52 is removed and the first coating layer 41 is formed, which entirely covers the exposed portions of the redistribution layer 25, until it makes contact with residual portions of the sacrificial layer 50 adjacent to the redistribution layer 25. As previously stated, the first coating layer 41 may be formed from nickel, or else, again by way of example, from a nickel-phosphorous (NiP), nickel-phosphorous-tungsten (NiPW) or nickel-phosphorous-molybdenum (NiPMo) alloy.

For example, the first coating layer 41 is formed on the exposed metal surfaces by means of a deposition technique known as electroless' deposition.

In greater detail, the first coating layer 41 covers the top and, in part, the sides of the redistribution layer 25, but does not make contact with the first barrier layer 22′ and the seed layer 24′, thanks to the protection provided by the sacrificial layer 50.

Subsequently, as shown in FIG. 11, the residual portions of the sacrificial layer 50 are removed, for example by means of a wet etch using hydrofluoric acid (HF). In this way, between the seed layer 24′ and the first coating layer 41 a cavity 45 is formed, which is laterally bounded by a lower portion of the redistribution layer 25.

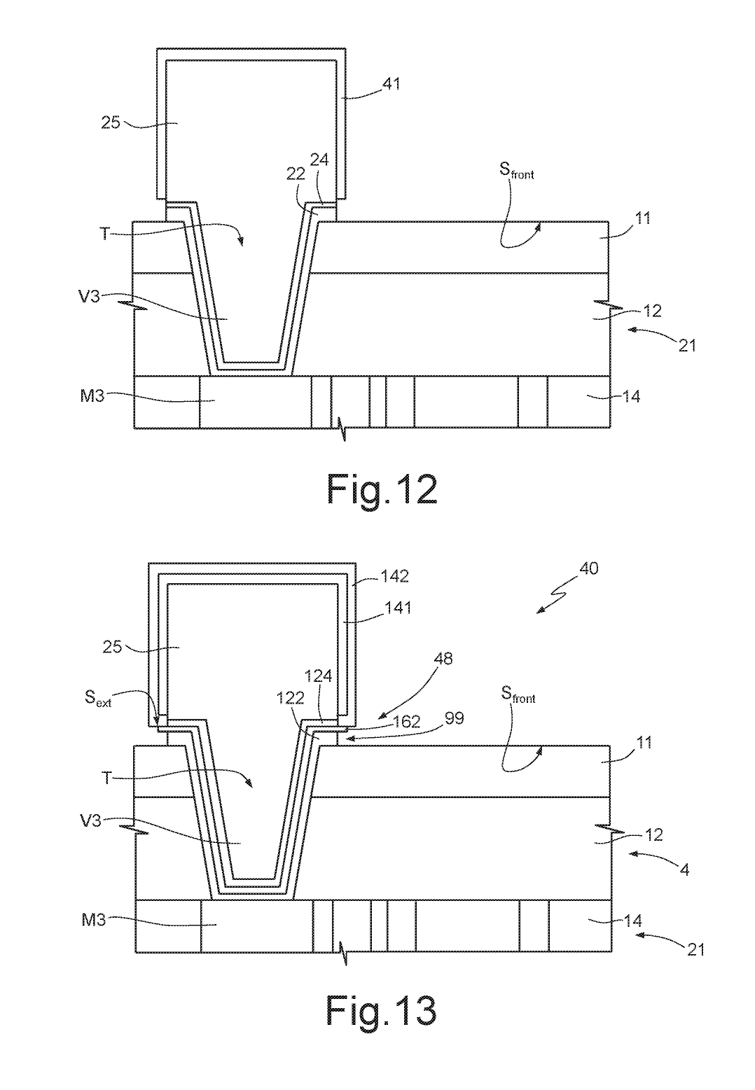

Subsequently, as shown in FIG. 12, two successive etches are carried out, for example of the wet type, with the aim of removing the exposed portions of the seed layer 24′, together with the underlying portions (which become exposed) of the first barrier layer 22′. In this way, the residual portions of the first barrier layer 22′ and of the seed layer 24′ respectively form the first patterned barrier layer 22 and the patterned seed layer 24.

In more detail, the etching of the exposed portions of the seed layer 24′ takes place in such a manner as to obtain an etch rate close to zero with regard to the portions of the first barrier layer 22′ that are exposed with this etch. Furthermore, for simplicity of visualization, the effects of this etch as regards the exposed portions of the redistribution layer 25 are not shown; furthermore, the effects on the first coating layer 41 are ignored.

In even further detail, the etching of the exposed portions of the first barrier layer 22′ takes place in such a manner as to obtain an etch rate of approximately zero with regard to the exposed portions of the redistribution layer 25, of the patterned seed layer 24 and of the coating layer 41.

For practical reasons, the redistribution layer 25 and the portions of the patterned seed layer 24 disposed on top of the frontal layer S_{front} form a single redistribution region. Similarly, the portion of the patterned seed layer 24 disposed inside of the hole T forms a kind of vertical conductive region together with the distal via V3.

The subsequent formation of the second coating layer 42 thus leads to what is shown in FIG. 2. For example, the second coating layer 42 is formed by means of a deposition of the electroless type and selectively grows on the exposed surfaces of the first coating layer 41. Furthermore, the thickness of the second coating layer 42 can be greater than the sum of the thicknesses of the sacrificial layer 50 and of the patterned seed layer 24, in such a manner that the second coating layer 42 laterally covers the sidewall of the patterned seed layer 24, i.e., it covers the sides of portions of the patterned seed layer 24 disposed on top of the frontal surface S_{front} and laterally offset with respect to the hole T, protecting it from oxidation. Furthermore, the second coating layer 42 covers laterally the portions of the redistribution layer 25 left exposed by the first coating layer 41, the latter portions being disposed on top of the aforementioned portions of the patterned seed layer 24.

According to a different embodiment, shown in FIG. 13, the integrated electronic device 40 comprises a second patterned barrier layer 162, which is interposed, in direct contact, between the first patterned barrier layer, here indicated with 122, and the patterned seed layer, here indicated with 124.

The second patterned barrier layer 162 is formed by a material having an etch rate lower than the etch rate of the first patterned barrier layer 122. For example, the second patterned barrier layer 162 may be formed by an alloy of titanium and tungsten having a different percentage of titanium compared with the alloy that forms the first barrier layer 122, or else may be formed by any given material from amongst, for example, titanium nitride (TiN), titanium (Ti), tantalum (Ta) or an alloy of tantalum and tantalum nitride (TaNTa). Furthermore, the second patterned barrier layer 162 has a thickness in the range for example between 4 nm and 40 nm.

In the embodiment shown in FIG. 13, the second patterned barrier layer 162 protrudes laterally both with respect to the underlying first patterned barrier layer 122 and with respect to the overlaid patterned seed layer 124, which have the same shape when viewed from above, to a first approximation. In other words, the second barrier layer 162 overhangs both with respect to the patterned seed layer 124 and with respect to the first barrier layer 122, and furthermore bounds from above a recess 99, which is bounded on the sides and on the bottom by the first patterned barrier layer 122 and by the first dielectric layer 11.

The first coating layer, here indicated with 141, also covers the top and sides of an upper portion of the redistribution layer 25 and is physically separated from the first and from the second patterned barrier layers 122, 162, and also from the patterned seed layer 124, given that the lower part extends down to a minimum height which is higher than the maximum height reached by the patterned seed layer 124.

The second coating layer, here indicated with 142, entirely covers the first coating layer 141 and furthermore covers laterally the portions of the redistribution layer 25 and of the patterned seed layer 124 left exposed by the first coating layer 141, which are disposed on top of the frontal surface S_{front} and are laterally offset with respect to the hole T.

More particularly, referring to the protruding surface Sₑₓₜ to indicate the surface that bounds from above the portion of the second patterned barrier layer 162 which laterally protrudes with respect to the patterned seed layer 124, the second coating layer 142 extends at the bottom until it entirely covers the protruding surface Sₑₓₜ, with which it is in direct contact. The second coating layer 142 may, in turn, laterally protrude with respect to the second patterned barrier layer 162.

The embodiment shown in FIG. 13 guarantees the same advantages described with reference to the embodiment shown in FIG. 2. Furthermore, the presence of a further barrier layer allows the possibility to be reduced of occurrence of phenomena of migration or electromigration of the material that forms the redistribution layer 25. In other words, the addition of the second patterned barrier layer 162 allows the metal material forming the redistribution layer 25 and the patterned seed layer 124 to be better encapsulated, with respect to the case in which only the first patterned barrier layer 22 is present.

The embodiment shown in FIG. 13 may be implemented by carrying out the fabrication process which is described hereinbelow, with reference to the differences with respect to the fabrication process shown in FIGS. 3-12.

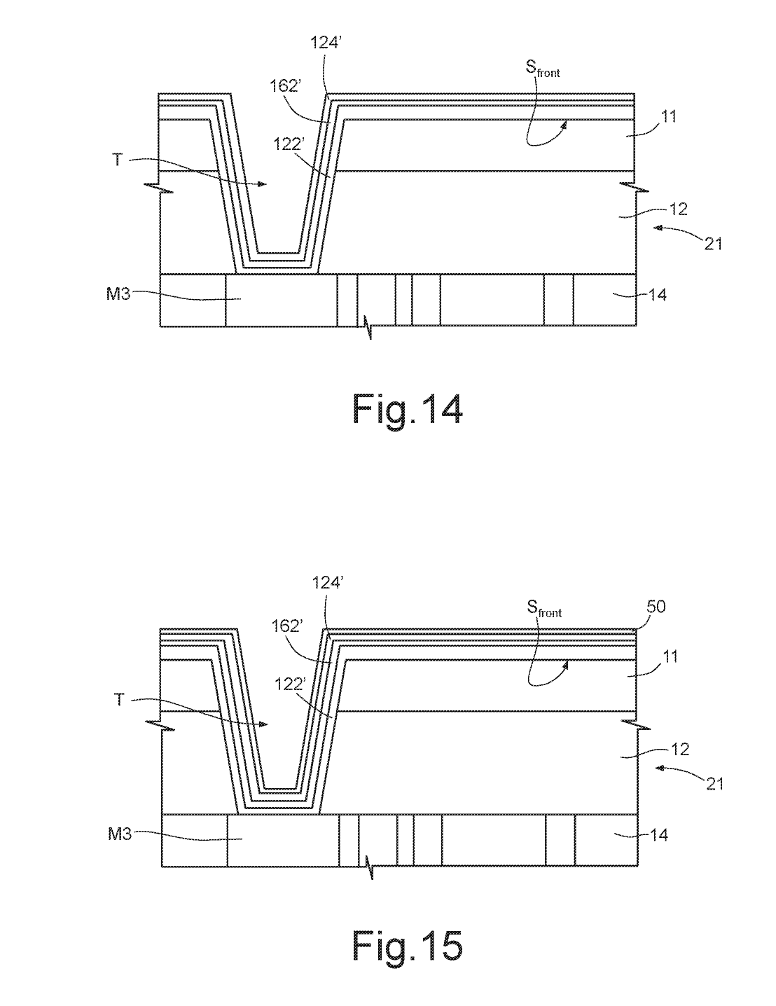

In detail, subsequent to the operations described with reference to FIGS. 3 and 4, the first barrier layer (here indicated with 122′), a second barrier layer (162′), destined to form the second patterned barrier layer 162, and the seed layer (here indicated with 124′) are formed. The second barrier layer 162′ is interposed between the first barrier layer 122′ and the seed layer 124′, as shown in FIG. 14.

Subsequently, as shown in FIG. 15, the sacrificial layer 50 is formed on top of the seed layer 124′.

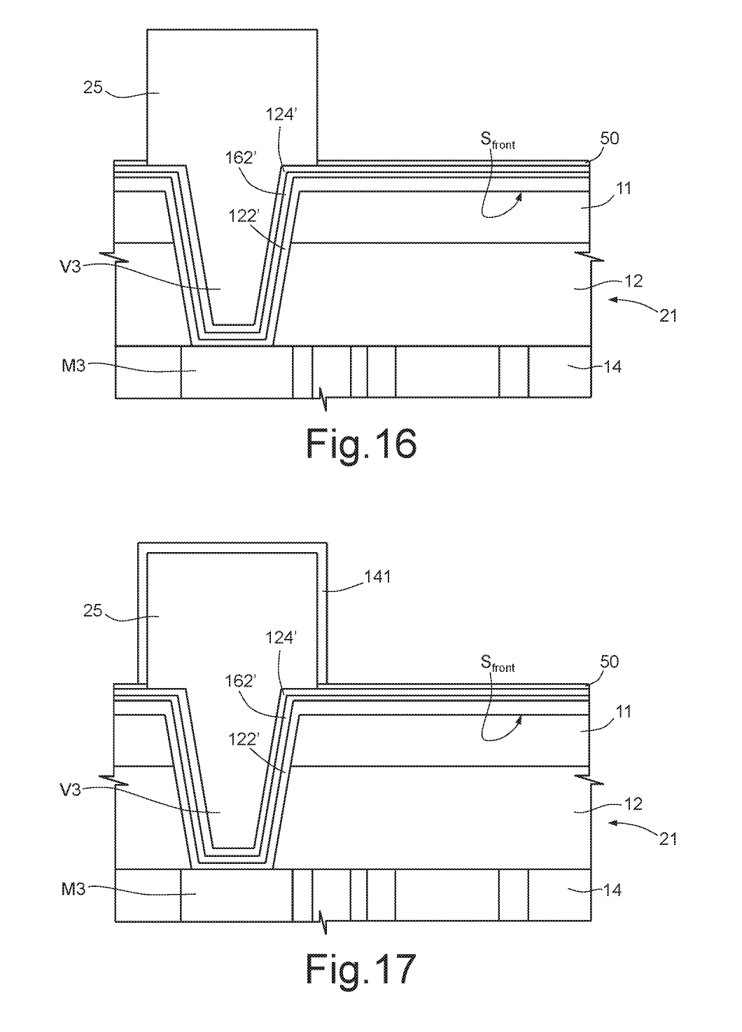

Subsequently, the same operations described with reference to FIGS. 7, 8, 9 are carried out with the aim of forming the redistribution layer 25 and the distal vias V3; these operations are not shown again and lead, following the removal of the resist mask 52, to the situation shown in FIG. 16.

Subsequently, as shown in FIG. 17, the first coating layer 141 is formed, which entirely covers the exposed portions of the redistribution layer 25, until it makes contact with portions of the sacrificial layer 50 adjacent to the redistribution layer 25. As previously said, the first coating layer 141 is selectively formed by means of an electroless deposition technique on the exposed metal surfaces.

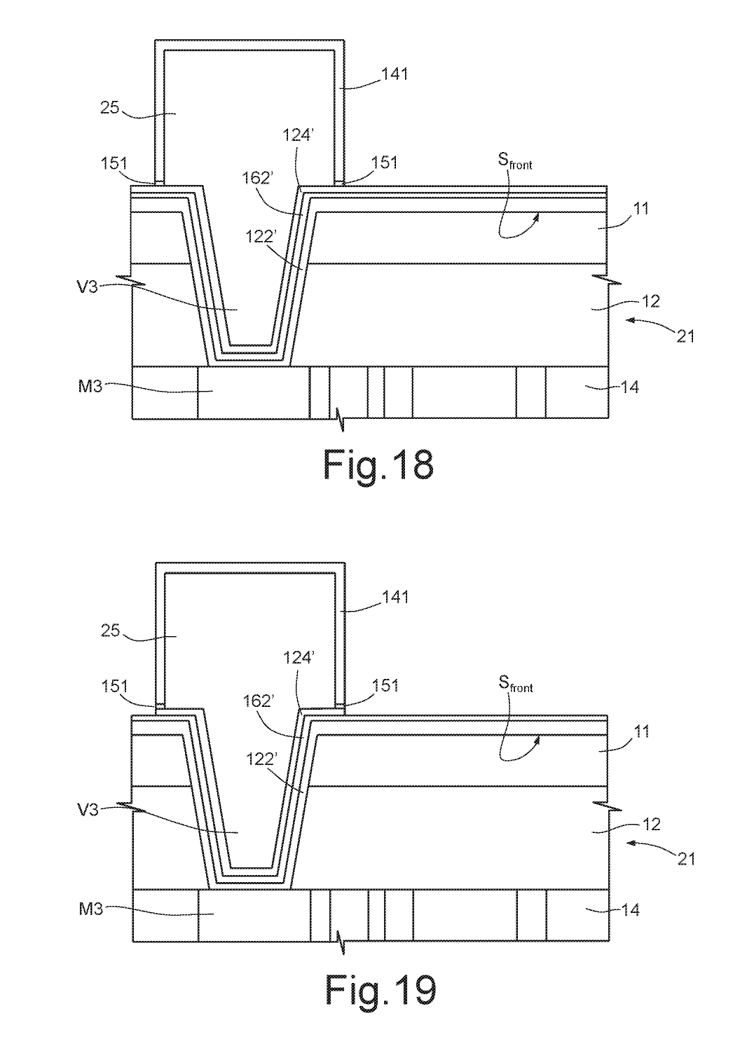

Subsequently, as shown in FIG. 18, the exposed portions of the sacrificial layer 50 are removed, for example by means of an etch of the wet type based on hydrofluoric acid (HF), or else by means of an etch of the dry type. Accordingly, underneath the first coating layer 141, there remains a residual dielectric region 151 which is in direct contact with the seed layer 124′, as well as with the first coating layer 141, and furthermore makes lateral contact with a lower portion of the redistribution layer 25.

Subsequently, as shown in FIG. 19, a further etch, for example of the wet type, is carried out with the aim of removing the exposed portions of the seed layer 124′, and thus exposing underlying portions of the second barrier layer 162′. Although not shown in FIG. 19, and without any loss of generality, following this etch, the residual dielectric region 151 can laterally protrude with respect to the residual portion of the seed layer 124′.

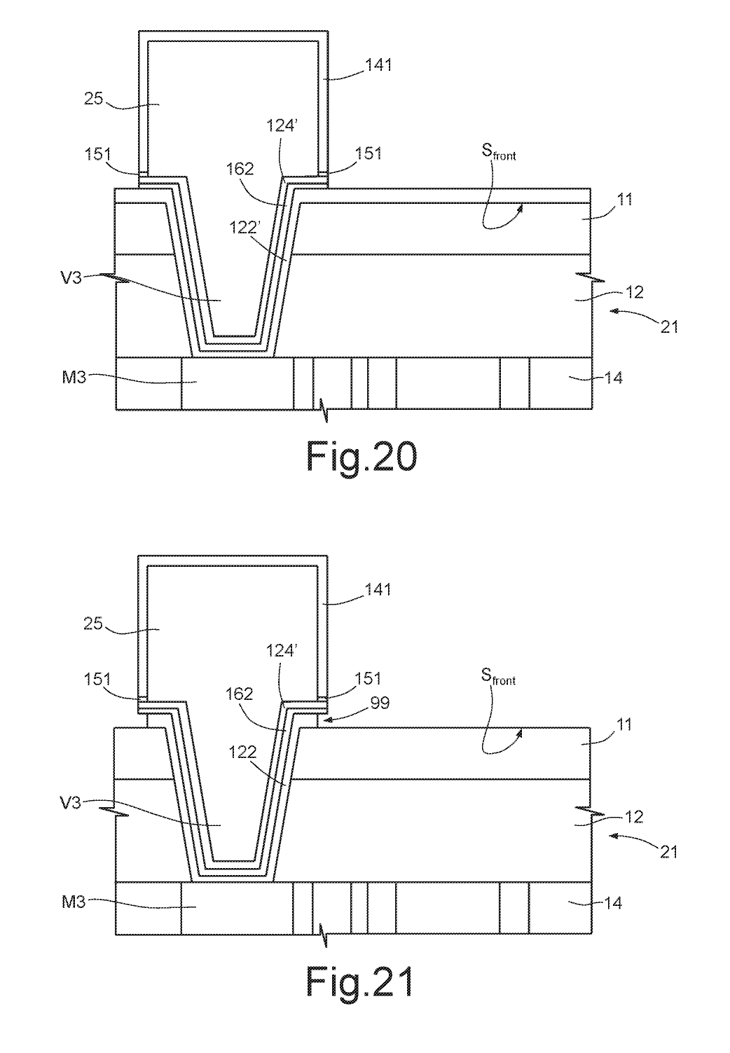

Following this, as shown in FIG. 20, a further etch, for example of the wet type, is carried out with the aim of selectively removing the exposed portions of the second barrier layer 162′. In this way, the residual portion of the second barrier layer 162′ forms, to a first approximation (i.e., ignoring the effects of the subsequent etches), the second patterned barrier layer 162 and has substantially the same shape, as viewed from above, as the residual portion of the seed layer 124′.

Subsequently, as shown in FIG. 21, a further etch, for example of the wet type, is carried out with the aim of selectively removing the exposed portions of the first barrier layer 122′, together with portions of the first barrier layer 122′ which extend underneath peripheral portions of the second patterned barrier layer 162 and which are disposed on top of the frontal surface S_{front} and are laterally offset with respect to the hole T. In this way, the recess 99 is formed; furthermore, the residual portion of the first barrier layer 122′ forms the first patterned barrier layer 122.

In more detail, the aforementioned selective etches of the portions of the first and of the second barrier layer 122′, 162′ take place in such a manner as not to etch, approximately, either the residual dielectric region 151 or the exposed portions of the seed layer 124′. Furthermore, these etches may take place based on the same chemistry (for example, hydrogen peroxide or a mixture of hydrogen peroxide and ammonium hydroxide) such that, as previously mentioned, the second barrier layer 162′ is formed by a material having a lower etch rate than the etch rate of the first barrier layer 122′. It is however possible for these etches to take place on the basis of different chemistries.

As previously mentioned, for simplicity of description, it may be assumed that, to a first approximation, the etch of the first barrier layer 122′ comprises a negligible etching of the residual material of the second barrier layer.

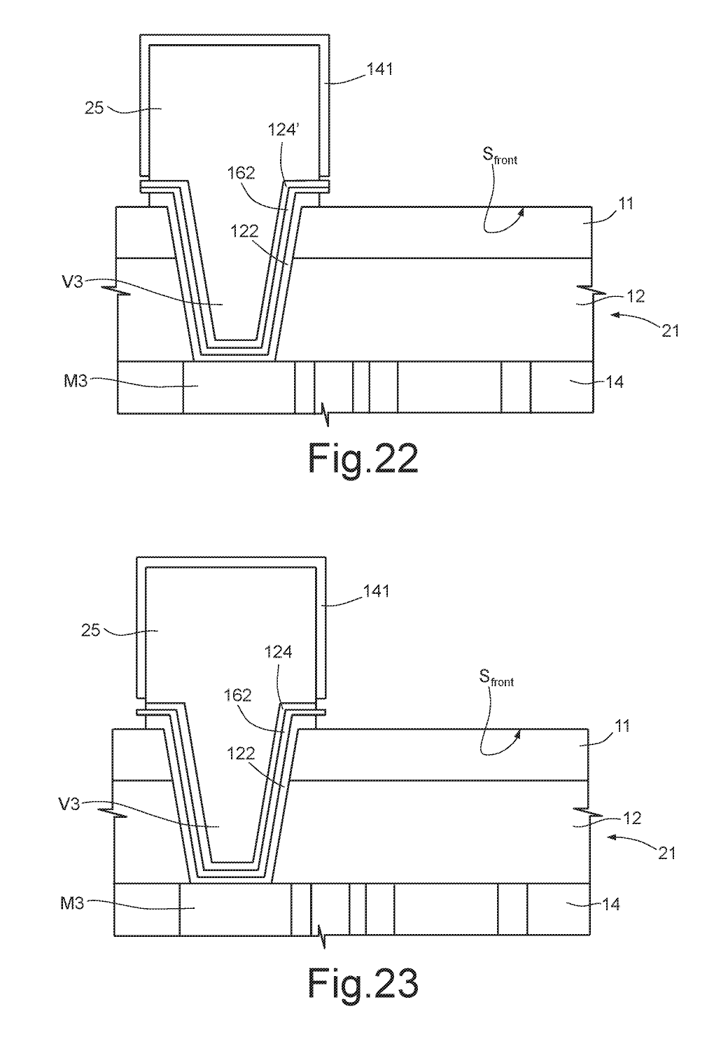

Subsequently, as shown in FIG. 22, the residual dielectric region 151 is selectively removed, for example by means of an etch of the wet type using hydrofluoric acid (HF). In this way, a peripheral portion of the seed layer 124′ is exposed on top, which is overlaid at a distance by the first coating layer 141; furthermore, the aforementioned lower portion of the redistribution layer 25 is exposed. To a first approximation, this selective etch of the residual dielectric region 151 does not comprise any modification of the seed layer 124′ or of the first and second patterned barrier layers 122, 162.

Subsequently, as shown in FIG. 23, a further etch, for example of the dSPM (diluted sulphuric acid hydrogen peroxide mixture) type, is carried out with the aim of selectively removing the exposed portion of the seed layer 124′. The residual portion of the seed layer 124′ thus forms the patterned seed layer 124. During this etch, the etch rates of the first and of the second patterned barrier layer 122, 162 are substantially zero.

Subsequently, the second coating layer 142 is formed, for example by means of an electroless deposition technique, such that it grows on the exposed surfaces of the first coating layer 41 and laterally coats the lower portion of the redistribution layer 25 and the patterned seed layer 124, in such a manner as to obtain the situation shown in FIG. 13.

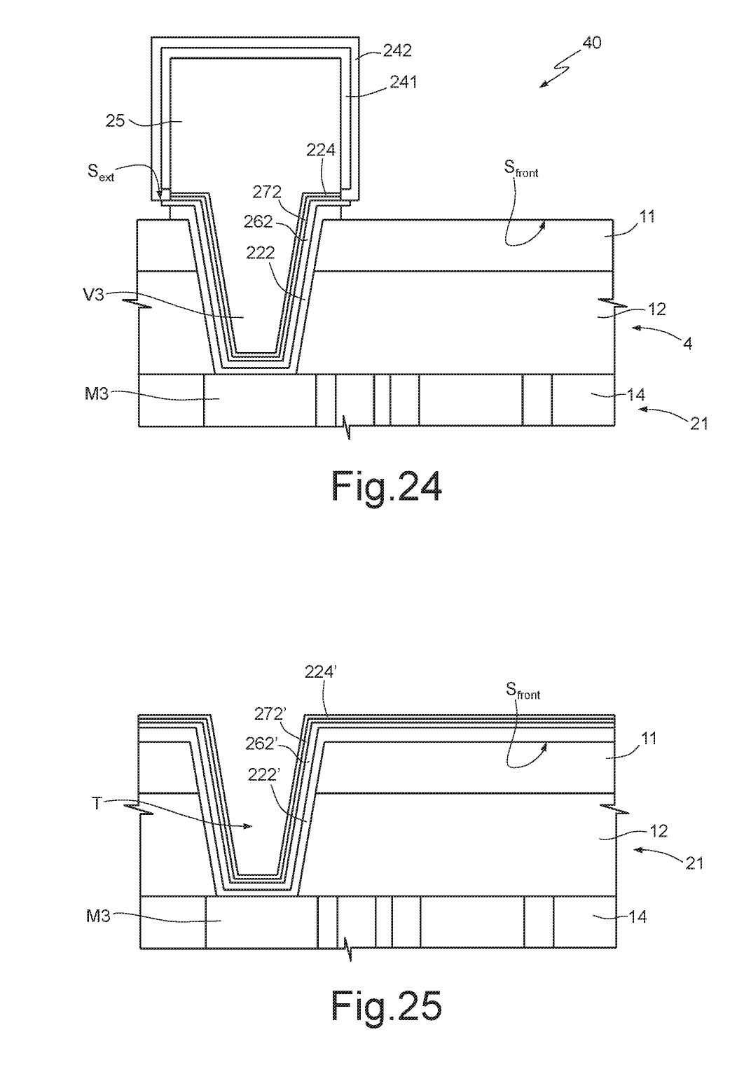

According to a different embodiment, shown in FIG. 24, the integrated electronic device 40 comprises a third patterned barrier layer 272, which is interposed, in direct contact, between the second patterned barrier layer (here indicated with 262) and the patterned seed layer (here indicated with 224).

The third patterned barrier layer 272 is formed by a material having an etch rate higher than the etch rate of the second patterned barrier layer 262. For example, the third patterned barrier layer 272 could be formed by an alloy of titanium and tungsten, or else could be formed by any given material from amongst, for example, titanium nitride (TiN), titanium (Ti), tantalum (Ta) or an alloy of tantalum and tantalum nitride (TaNTa).

In addition, the second patterned barrier layer 262 protrudes laterally both with respect to the underlying first patterned barrier layer (here indicated with 222), with which it bounds the recess 99, and with respect to the overlaid third patterned barrier layer 272. Furthermore, without any loss of generality, the patterned seed layer 224 and the third patterned barrier layer 272 can have the same shape as viewed from above. Again, without any loss of generality, the third patterned barrier layer 272 may protrude laterally with respect to the first patterned barrier layer 222.

In practice, the embodiment shown in FIG. 24 includes a barrier structure of the multilayer type, in which adjacent barrier layers have different chemical compositions; furthermore, one of the patterned barrier layers (in particular, the second patterned barrier layer 262), different from the layer that makes contact with the first dielectric layer 11, protrudes laterally with respect to the other patterned barrier layers, i.e., it includes portions that overhang with respect to the other patterned barrier layers.

The first coating layer, here indicated with 241, again covers an upper portion of the redistribution layer 25 on the top and sides and is physically separated from the first, from the second and from the third patterned barrier layers 222, 262, 272, and also from the patterned seed layer 224, given that it extends at the bottom down to a minimum height which is higher than the maximum height reached by the patterned seed layer 224.

The second coating layer, here indicated with 242, entirely covers the first coating layer 241 and furthermore covers laterally a lower portion of the redistribution layer 25 and the portions of the patterned seed layer 224 and of the third patterned barrier layer 272 which extend over the frontal surface S_{front}, as far as covering the protruding surface Sₑₓₜ, i.e., until contact is made with the overhanging portions of the second patterned barrier layer 262.

The embodiment shown in FIG. 24 guarantees the same advantages described with reference to the embodiment shown in FIG. 13. Furthermore, the addition of the third patterned barrier layer 272 allows the adhesion between the barriers and the seed layer 224 to be enhanced.

The embodiment shown in FIG. 24 may be produced by carrying out the fabrication process described hereinbelow.

In detail, subsequent to the operations described with reference to FIGS. 3 and 4, the first barrier layer (here indicated with 222′), the second barrier layer (here indicated with 262′), a third barrier layer 272′, destined to form the third patterned barrier layer 272, and the seed layer (here indicated with 224′) are formed. The third barrier layer 272′ is interposed between the second barrier layer 262′ and the seed layer 224′, as shown in FIG. 25.

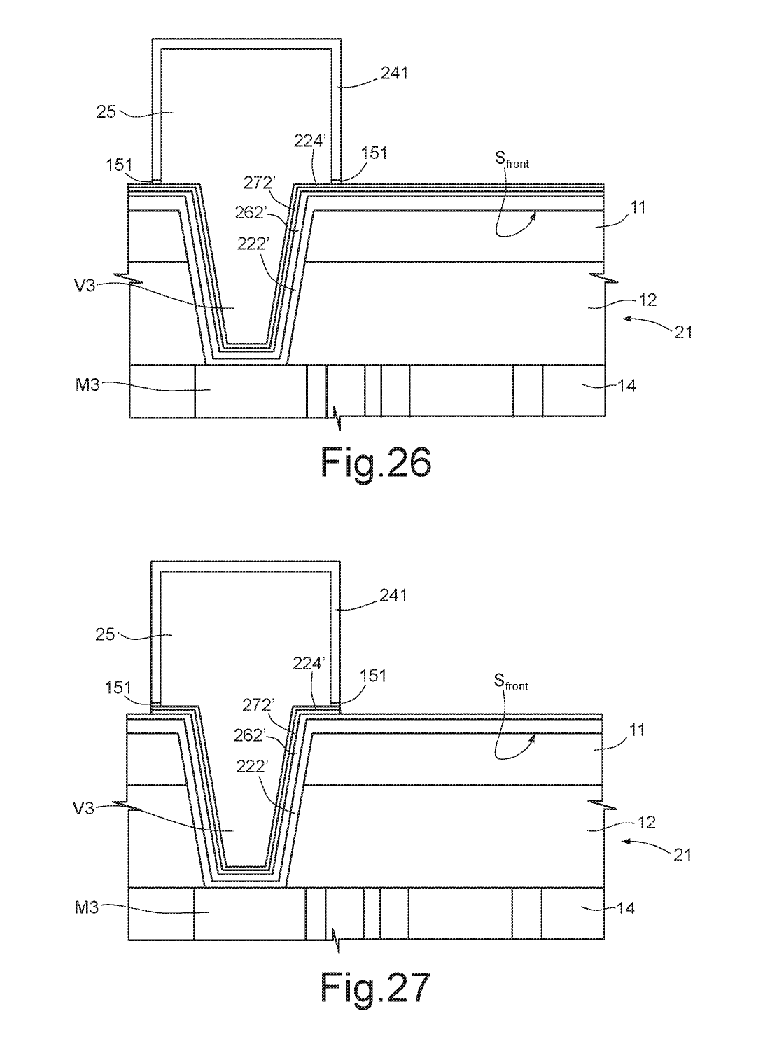

Subsequently, operations analogous to those described with reference to FIGS. 15-18 are carried out, which comprise, inter alia, the formation of the sacrificial layer 50 on the seed layer 224′. At the end of these operations, the integrated electronic device 40 takes the form shown in FIG. 26, in which, amongst other things, the presence of the residual dielectric region 151 is shown, which is interposed between the first coating layer 241 and the seed layer 224′ and has sidewalls aligned with the sidewalls of the first coating layer 241.

Subsequently, as shown in FIG. 27, the operations described with reference to FIG. 19 are carried out, together with a further etch, for example of the wet type, with the aim of selectively removing the exposed portions of the third barrier layer 272′. Following these operations, the residual portion of the third barrier layer 272′ has, as viewed from above, the same shape as the first coating layer 241, i.e., it has sidewalls aligned with the sidewalls of the first coating layer 241. Also, the residual portion of the seed layer 224′ has sidewalls aligned with the sidewalls of the first coating layer 241.

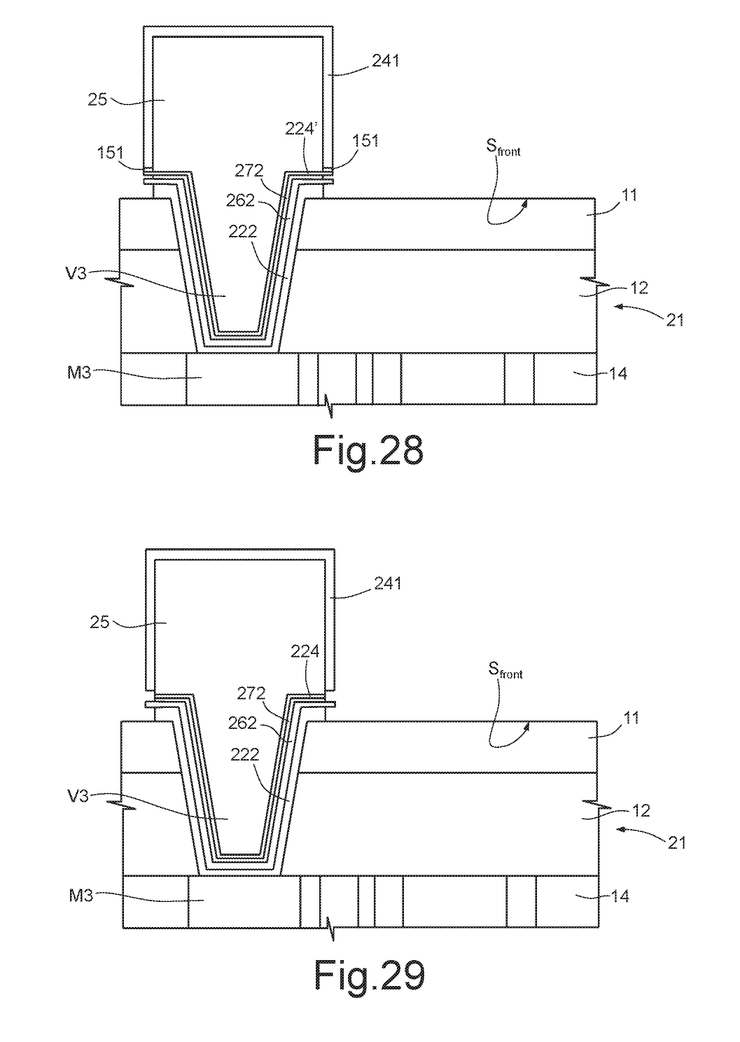

Subsequently, as shown in FIG. 28, another two etches, for example of the wet type, are carried out with the aim of removing the exposed portions of the second barrier layer 262′ (thus forming the second patterned barrier layer 262, if the effects of the subsequent etches are ignored) and, subsequently, the portions of the first barrier layer 222′ which have become exposed and portions of the first barrier layer 222′ which extend under peripheral portions of the second patterned barrier layer 262. In this way, the residual portions of the first barrier layer 222′ form the first patterned barrier layer 222 (if the effects of the subsequent etches are ignored); furthermore, subsequent to these etches, the residual portions of the third barrier layer 272′ form the third patterned barrier layer 272, if for the sake of simplicity the effects of the subsequent etches are ignored.

In greater detail, the three successive etches of the third, of the second and of the first barrier layer 272′, 262′ and 222′ may be carried out based on the same chemistry (for example, hydrogen peroxide or a mixture of hydrogen peroxide and ammonium hydroxide).

Next, as shown in FIG. 29, the residual dielectric region 151 is removed, for example by means of an etch of the wet type using hydrofluoric acid (HF). Furthermore, a further etch is carried out, for example of the dSPM type, with the aim of removing the exposed portions of the seed layer 224′. The residual portion of the seed layer 224′ thus forms the patterned seed layer 224. Furthermore, the first coating layer 241 is formed.

Subsequently, the second coating layer 242 is formed, for example by means of electroless deposition, such that it grows on the exposed surfaces of the first coating layer 241, in such a manner as to obtain the situation shown in FIG. 24.

The advantages that are offered by the present integrated electronic device are clearly apparent from the preceding description. In particular, the present integrated electronic device disposes of a frontal structure such that the passivation structure is subjected to lower mechanical stresses, compared with known devices. Furthermore, in the case in which more than one barrier layer is present, the protruding barrier layer represents a sort of buffer layer, which can give way in the case of excessive stresses, in such a manner as to allow the relaxing of these stresses without further damage being caused inside of the integrated electronic device.

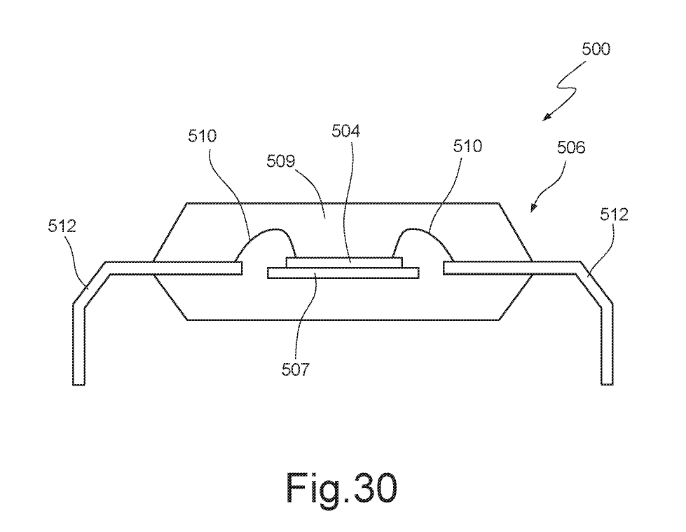

As shown in FIG. 30, subsequent to the process of dicing of the die 4, the present integrated electronic device 40 may for example form a chip 500, which includes the individual die, indicated with 504, together with a lead frame 506. The chip 500 furthermore comprises an encapsulation or packaging region 509, which is formed for example by an epoxy resin, and one or more conducting wires 510.

In more detail, the lead frame 506 comprises a pad 507, on which the individual die 504 rests, and a plurality of terminals 512, each of which extends in part inside of the packaging region 509 and in part outside. Furthermore, the terminals 512 are electrically coupled to the individual die 504 through the conducting wires 510, which implement corresponding wire bondings and make contact with the redistribution layer 25/palladium layer (detail not visible in FIG. 30). The packaging region 509 surrounds the individual die 504, the pad 507 and the conducting wires 510.

Finally, it will be clear that modifications and variants may be applied to the present integrated electronic device and to the related fabrication process, without straying from the scope of the present disclosure.

For example, the passivation structure may be different compared with that described. Furthermore, the first and the second coating layer, the first patterned barrier layer and, where present, the second and the third patterned barrier layer may have different thicknesses with respect to those described and may be formed from materials different from those described.

It is furthermore possible for the vias formed in a monolithic manner with the redistribution layer to be different from the distal vias. More generally, the level of the vias integrated with the redistribution layer is irrelevant. Even more generally, the same reference to RDL technology, intended as characteristic thicknesses and materials, is irrelevant for the purposes of the present integrated electronic device.

There are furthermore possible embodiments in which a further metal layer, formed for example from gold, extends over the second coating layer.

With regard to the fabrication process, some of the steps described may be carried out in a different order with respect to that described. Furthermore, it is possible for the fabrication process to include steps not described hereinabove, such as for example a step for processing the edges of the die and a thermal treatment, which are for example carried out after having formed the redistribution layer, prior to forming the first coating layer.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An integrated electronic device, comprising:
a semiconductor body;
a passivation structure on the semiconductor body, the passivation structure including a frontal dielectric layer bounded by a frontal surface;
a conductive region of a first metal material including a via region extending into a hole passing through the frontal dielectric layer, and the conductive region including an overlaid redistribution region extending over the frontal surface and having an upper portion including a top and sides and having a lower portion;
a barrier structure including at least a first barrier region of a second metal material extending into the hole and surrounding the via region, the first barrier region including top portions extending over the frontal surface;
a first coating layer of a third metal material covering the top and the sides of an upper portion of the overlaid redistribution region at a distance from the frontal surface; and
a second coating layer of a fourth metal material extending at a distance from the frontal surface, the second coating layer covering the first coating layer and covering laterally the lower portion of the overlaid redistribution region disposed on the top of portions of the barrier structure extending over the frontal surface.

2. The device according to claim 1, wherein the barrier structure further comprises a second barrier region of a fifth metal material extending over the first barrier region and protruding laterally with respect to the first barrier region, the fifth material being different from the second material, and the second coating layer extending at a bottom portion proximate the frontal surface to make contact with the second barrier region.

3. The device according to claim 2, wherein the barrier structure further comprises a third barrier region formed from a sixth metal material and extending over the second barrier region, the sixth material being different from the fifth material, the second barrier region protruding laterally with respect to the third barrier region and the third barrier region being laterally covered by the second coating layer.

4. The device according to claim 3, wherein the third metal material has a greater hardness than a hardness of the first material.

5. The device according to claim 4, wherein the fourth metal material of the second coating layer protects from oxidation the first coating layer and lower portion of the overlaid redistribution region.

6. The device according to claim 5, wherein the barrier structure is configured to prevent migration of the first metal material to the passivation structure.

7. The device according to claim 6, wherein the first, third and fourth metal materials are respectively:
copper;
nickel or an alloy of nickel; and
gold or palladium or palladium/gold.

8. An integrated circuit, comprising:
a die including an integrated electronic device, the integrated electronic device further including:
a semiconductor body;
a passivation structure on the semiconductor body, the passivation structure including a frontal dielectric layer bounded by a frontal surface;
a conductive region including a via region extending into a hole passing through the frontal dielectric layer, the conductive region including an overlaid redistribution region extending over the frontal surface and having an upper portion including a top and sides and having a lower portion;
a barrier structure including at least a first barrier region extending into the hole and surrounding the via region, the first barrier region including top portions extending over the frontal surface;
a first coating layer covering the top and the sides of an upper portion of the overlaid redistribution region at a distance from the frontal surface; and
a second coating layer extending at a distance from the frontal surface, the second coating layer covering the first coating layer and covering laterally the lower portion of the overlaid redistribution region disposed on the top of portions of the barrier structure extending over the frontal surface;
a dielectric encapsulation region surrounding the die; and
at least one conductive terminal extending in part inside of the dielectric encapsulation region and in part outside of the dielectric encapsulation region, the at least one conductive terminal being electrically coupled through a conducting wire to the redistribution region.

9. The integrated circuit of claim 8, wherein the passivation structure further comprises:
a distal metallization layer in contact with the barrier structure;
intermediate vias having first and second ends, the first ends being in contact with the distal metallization layer;
an intermediate metallization layer in contact with the second ends of the intermediate vias;
proximal vias having first and second ends, the first ends being in contact with the intermediate metallization layer;
a proximal metallization layer in contact with the second ends of the proximal vias;
contact regions having first ends in contact with the proximal metallization layer and having second ends; and
a semiconductor body in contact with the second ends of the contact regions.

10. The integrated circuit of claim 8, wherein the barrier structure further comprises a third barrier region formed extending over the second barrier region, the second barrier region protruding laterally with respect to the third barrier region and the third barrier region being laterally covered by the second coating layer.

11. The integrated circuit of claim 8, wherein the conductive region includes a first metal material, the at least the first barrier region includes a second metal material, the first coating layer includes a third metal material, and the second coating layer includes a fourth metal material.

12. A fabrication process for an integrated electronic device, comprising:
forming a hole through a frontal dielectric layer of a die including a semiconductor body and a passivation structure including the frontal dielectric layer, the frontal dielectric layer having a frontal surface;
forming a via region extending into the hole;
forming a redistribution region over the via region and extending over the frontal surface of the frontal dielectric layer, the redistribution region including an upper portion including a top and sides, and a lower portion of the redistribution region proximate the frontal surface of the frontal dielectric layer;
forming a first barrier region extending into the hole and surrounding the via region, the first barrier region including portions extending over the frontal surface;
forming a first coating layer on the top and sides of the upper portion of the redistribution region, the first coating layer having a portion proximate the frontal surface but at a distance and physically separated from the frontal surface; and
forming a second coating layer over the first coating layer and covering laterally the lower portion of the redistribution region and portions of the first barrier region extending over the frontal surface.

13. The fabrication process according to claim 12, wherein forming the first barrier region comprises:
forming, on top of the frontal surface and inside of the hole, a first barrier layer;
forming, on top of the first barrier layer, a seed layer;
forming, on top of the seed layer, a dielectric sacrificial layer;
forming, on top of the dielectric sacrificial layer, a mask which defines a window exposing a portion of the dielectric sacrificial layer that overlies a part of the seed layer, the part of the seed layer including the portion of seed layer disposed inside of the hole and portions of the seed layer protruding laterally with respect to the hole over the frontal surface; and
through the mask, removing the exposed portion of the dielectric sacrificial layer to expose the part of the seed layer.

14. The fabrication process according to claim 13, wherein forming the via and redistribution regions comprises forming, through the mask and by means of electrochemical growth starting from the exposed part of the seed layer, a conductive via which extends into the hole and a redistribution layer which overlies the conductive via and the portions of the seed layer which protrude laterally with respect to the hole.

15. The fabrication process of claim 14, further comprising:
removing the mask; and
wherein forming the first coating layer includes forming the first coating layer covering the top and the sides of the upper portion of the redistribution layer until the first coating layer makes contact with residual portions of the dielectric sacrificial layer adjacent to the redistribution layer.

16. The fabrication process of claim 15 further comprising, after the formation of the redistribution layer, the operations of:
removing the residual portions of the dielectric sacrificial layer to expose underlying portions of the seed layer and to expose sides of the lower portion of the redistribution layer;
selectively removing the exposed portions of the seed layer and underlying portions of the first barrier layer; and
forming, by means of selective growth starting from the first coating layer, the second coating layer to cover laterally the lower portion of the redistribution layer and remaining portions of the seed layer.

17. The fabrication process according to claim 15, wherein forming the first barrier region further comprises:
forming a second barrier region extending over the first barrier region and protruding laterally with respect to the first barrier region; and
wherein forming the second coating layer includes forming the second coating layer extending proximate the frontal surface until the second coating layer makes contact with the second barrier region.

18. The fabrication process according to claim 17, wherein forming the first barrier region further comprises:
forming, on top of the frontal surface and inside of the hole, a first barrier layer and a second barrier layer;
forming, on top of the second barrier layer, a seed layer;
forming, on top of the seed layer, a dielectric sacrificial layer;
forming, on top of the dielectric sacrificial layer, a mask defining a window exposing a portion of the dielectric sacrificial layer that overlies a part of the seed layer, the part of the seed layer including the portion of seed layer disposed inside of the hole and portions of the seed layer that protrude laterally with respect to the hole over the frontal surface; and
through the mask, removing the exposed portion of the dielectric sacrificial layer to expose the part of the seed layer;
and wherein forming the via region and redistribution region includes forming, through the mask and by means of electrochemical growth starting from the exposed part of the seed layer, a conductive via which extends into the hole and a redistribution layer that overlies the conductive via and the portions of the seed layer that protrude laterally with respect to the hole; and
wherein the fabrication process further includes removing the mask;
wherein forming the first coating layer includes forming the first coating layer covering the top and the sides of an upper portion of the redistribution layer until the first coating layer makes contact with residual portions of the dielectric sacrificial layer adjacent to the redistribution layer; and
wherein the fabrication process further includes, after the formation of the redistribution layer, the operations of:
partially removing the residual portions of the dielectric sacrificial layer, to form a residual dielectric region interposed between the first coating layer and the seed layer and making lateral contact with the lower portion of the redistribution layer and exposing underlying portions of the seed layer; and subsequently
selectively removing the exposed portions of the seed layer to expose underlying portions of the second barrier layer; and subsequently
carrying out a first etch for removing the exposed portions of the second barrier layer, exposing underlying portions of the first barrier layer, and then carrying out a second etch for removing the exposed portions of the first barrier layer and portions of the first barrier layer disposed on top of the frontal surface and underneath the portions of the second barrier layer that remain after the first etch, the an etch rate of the second barrier layer being lower than an etch rate of the first barrier layer; and subsequently
selectively removing the residual dielectric region to expose sides of the lower portion of the redistribution layer and to expose a top of peripheral portions of the seed layer; and subsequently
selectively removing the peripheral portions of the seed layer; and
forming, by means of selective growth starting from the first coating layer, the second coating layer covering laterally the lower portion of the redistribution layer and remaining portions of the seed layer.

19. The fabrication process according to claim 17, wherein forming the first barrier region further comprises:
forming a third barrier region, the third barrier region extending over the second barrier region; and
wherein the second barrier region protrudes laterally with respect to the third barrier region which is covered laterally by the second coating layer.

20. The fabrication process according to claim 19, wherein forming the first barrier region comprises:
forming, on top of the frontal surface and inside of the hole, a first barrier layer, a second barrier layer and a third barrier layer;
forming, on top of the third barrier layer, a seed layer;
forming, on top of the seed layer, a dielectric sacrificial layer;
forming, on top of the dielectric sacrificial layer, a mask defining a window exposing a portion of the dielectric sacrificial layer which overlies a part of the seed layer, the part of the seed layer including the portion of seed layer disposed inside of the hole and portions of the seed layer which protrude laterally with respect to the hole over the frontal surface;
through the mask, removing the exposed portion of the dielectric sacrificial layer to expose the part of the seed layer;
wherein forming the via region and the redistribution region includes forming, through the mask and by means of electrochemical growth starting from the exposed part of the seed layer, a conductive via extending into the hole and a redistribution layer which overlies the conductive via and said portions of the seed layer protruding laterally with respect to the hole;
wherein the fabrication process further includes removing the mask;
wherein forming the first coating layer includes forming the first coating layer covering the top and the sides of an upper portion of the redistribution layer until the first coating layer makes contact with residual portions of the dielectric sacrificial layer adjacent to the redistribution layer;
wherein the fabrication process further includes, after the formation of the redistribution layer, the operations of:
partially removing the residual portions of the dielectric sacrificial layer to form a residual dielectric region interposed between the first coating layer and the seed layer and making lateral contact with the redistribution layer, and exposing portions of the seed layer; and subsequently
selectively removing the exposed portions of the seed layer to expose underlying portions of the third barrier layer; and subsequently
carrying out a first etch for removing the exposed portions of the third barrier layer to expose underlying portions of the second barrier layer, and then carrying out a second etch for removing the exposed portions of the second barrier layer to expose underlying portions of the first barrier layer, and then carrying out a third etch for removing the exposed portions of the first barrier layer and portions of the first barrier layer disposed on top of the frontal surface and underneath the portions of the second barrier layer that remain after the second etch, an etch rate of the second barrier layer being lower than an etch rate of the first barrier layer; and subsequently
selectively removing the residual dielectric region to expose sides of the lower portion of the redistribution layer and to expose a top of peripheral portions of the seed layer; and subsequently
selectively removing said peripheral portions of the seed layer; and subsequently
forming, by means of selective growth of the fourth material starting from the first coating layer, the second coating layer covering laterally the lower portion of the redistribution layer, remaining portions of the seed layer and of the third barrier layer.
